(19) United States
(12) Patent Application Publication
(10) Pub. No.: US 2026/0076214 A1
(43) Pub. Date: Mar. 12, 2026

(54) SEMICONDUCTOR DEVICES

(71) Applicant: Samsung Electronics Co., Ltd., Suwon-si (KR)

(72) Inventors: Myeongcheol GO, Suwon-si (KR); Jeonghyun KIM, Suwon-si (KR); Ilhwan KIM, Suwon-si (KR); Jonghwa BAEK, Suwon-si (KR); Hachul SHIN, Suwon-si (KR); Youngjae LEE, Suwon-si (KR)

(73) Assignee: Samsung Electronics Co., Ltd., Suwon-si (KR)

(21) Appl. No.: 19/254,240

(22) Filed: Jun. 30, 2025

(30) Foreign Application Priority Data
Sep. 9, 2024 (KR) 10-2024-0122411

(51) Int. Cl. H01L 23/544

(52) U.S. Cl. CPC H10W 46/00; H10W 46/301

(57) ABSTRACT

A semiconductor device includes a substrate including a key region; dummy active structures on the key region, extending in a first direction parallel to an upper surface of the substrate, spaced apart from each other in a second direction perpendicular to the first direction, and each including at least one dummy active region; a dummy device isolation layer in the key region and defining the at least one dummy active region; and a dummy upper isolation structure on the dummy device isolation layer and a portion of each of the dummy active structures and including first patterns extending in the first direction.

### CROSS-REFERENCE TO RELATED APPLICATION(S)

This application claims benefit of priority to Korean Patent Application No. 10-2024-0122411 filed on Sep. 9, 2024 in the Korean Intellectual Property Office, the disclosure of which is incorporated herein by reference in its entirety.

### BACKGROUND

Some example embodiments relate to a semiconductor device.

As desire for high performance, high speed, and/or multifunctionality in a semiconductor device has increased, integration of a semiconductor device has increased. In manufacturing a semiconductor device having fine patterns corresponding to the trend toward high integration density of a semiconductor device, it may be important to implement patterns having a fine width or a fine spacing. Alternatively or additionally, in order to overcome or at least partly overcome limitations in operating properties due to reduction in a size of a planar metal oxide semiconductor FET (MOSFET), an effort has been made to develop a semiconductor device including transistors with channels having a three-dimensional structure.

### SUMMARY

Some example embodiments may provide a semiconductor device having improved reliability.

According to some example embodiments, a semiconductor device includes a substrate including first and second regions; active regions on the first region and extending in a first direction; a device isolation layer defining the active regions in the first region; gate structures on the first region, intersecting the active regions, and extending in a second direction; a plurality of channel layers on the active regions, spaced apart from each other in a third direction perpendicular to an upper surface of the substrate, and surrounded by each of the gate structures; source/drain regions in recess regions in which the active regions are recessed on first and second sides of the gate structures and connected to the plurality of channel layers; and an isolation structure between the gate structures, between the plurality of channel layers, and between the source/drain regions adjacent to each other in the second direction, and the isolation structure including a lower isolation structure and an upper isolation structure on the lower isolation structure; dummy active structures on the second region and including at least one dummy active region; a dummy device isolation layer defining the dummy active regions in the second region; and a dummy upper isolation structure on the dummy device isolation layer and the dummy active structures, overlapping edge regions of the dummy active structures in the third direction. The dummy upper isolation structure includes first patterns extending in the first direction or the second direction, and second patterns connecting ends of the first patterns. At least a portion of the dummy upper isolation structure is at a same level as the upper isolation structure.

Alternatively or additionally according to some example embodiments, a semiconductor device includes a substrate including a key region; and first and second key structures on the key region. The first key structure includes first dummy active structures on the key region, extending in a first direction parallel to an upper surface of the substrate, and spaced apart from each other in a second direction perpendicular to the first direction; and a first dummy upper isolation structure on the first dummy active structures and having first openings exposing a portion of each of the first dummy active structures in plan view. The second key structure includes second dummy active structures on the key region, extending in the second direction, and spaced apart from each other in the first direction; and a second dummy upper isolation structure on the second dummy active structures and having second openings exposing a portion of each of the second dummy active structures in plan view.

Alternatively or additionally according to some example embodiments, a semiconductor device includes a substrate including a key region; dummy active structures on the key region, extending in a first direction parallel to an upper surface of the substrate, spaced apart from each other in a second direction perpendicular to the first direction, and respectively including at least one dummy active region; a dummy device isolation layer defining the at least one dummy active region in the key region; and a dummy upper isolation structure on the dummy device isolation layer and a portion of each of the dummy active structures, the dummy upper isolation structure including first patterns extending in the first direction.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan view illustrating a semiconductor device according to some example embodiments;

FIGS. 2A and 2B are plan views illustrating a semiconductor device according to some example embodiments;

FIGS. 3A and 3B are cross-sectional views illustrating a semiconductor device according to some example embodiments;

FIGS. 4A and 4B are a cross-sectional view and a perspective view illustrating a semiconductor device according to some example embodiments;

FIGS. 5A to 5D are plan views illustrating a semiconductor device according to some example embodiments;

FIGS. 6A and 6B are cross-sectional views illustrating a semiconductor device according to some example embodiments;

FIGS. 7A and 7B are cross-sectional views illustrating a semiconductor device according to some example embodiments; and

FIGS. 8A to 8H are views illustrating processes of a method of manufacturing a semiconductor device in order according to some example embodiments.

### DETAILED DESCRIPTION

Hereinafter, some example embodiments will be described as follows with reference to the accompanying drawings.

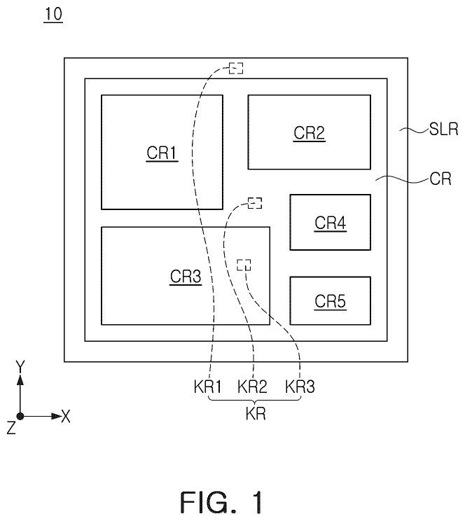

FIG. 1 is a plan view illustrating a semiconductor device according to some example embodiments.

Referring to FIG. 1, a semiconductor device 10 may include a circuit region CR and a kerf line region or scribe line region SLR surrounding the circuit region CR. The semiconductor device 10 may further include key regions KR positioned in at least one of the circuit region CR or the scribe line region SLR.

The scribe line region SLR may be or may correspond to a region remaining after a dicing process is performed along a scribe line on a wafer on which the semiconductor device 10 is formed. The scribe line region SLR may be or may correspond to a region including at least a portion of the scribe line before the dicing process. The scribe line region SLR may include a first key region KR1. In the scribe line region SLR, the number and/or the arrangement position of the first key region KR1 may be varied in example embodiments.

The circuit region CR may also be referred to as a chip region and may include a number of circuit regions, for example, first to fifth circuit regions CR1, CR2, CR3, CR4, and CR5. Each of the first to fifth circuit regions CR1, CR2, CR3, CR4, and CR5 may be or may correspond to a functional block included in an integrated circuit. Each of the first to fifth circuit regions CR1, CR2, CR3, CR4, and CR5 may independently include at least one of a memory block, an analog logic block, an input/output (I/O) logic block, a central processing unit (CPU) block, or a radio frequency block. In some example embodiments, each of the first to fifth circuit regions CR1, CR2, CR3, CR4, and CR5 may include the same, or different, ones of a memory block, an analog logic block, an input/output (I/O) logic block, a central processing unit (CPU) block, or a radio frequency block, and may have the same or different size and/or the same or different shape. The circuit region CR may further include a second key region KR2 and a third key region KR3. For example, the second key region KR2 may be disposed between the first to fifth circuit regions CR1, CR2, CR3, CR4, and CR5, and the third key region KR3 may be disposed in the third circuit region CR3.

The key regions KR may include first to third key regions KR1, KR2, and KR3 disposed at different positions in the semiconductor device 10 as described above. However, in the semiconductor device 10, at least one of the first to third key regions KR1, KR2, and KR3 may not be provided. For example, the semiconductor device 10 may include only one of the first to third key regions KR1, KR2, or KR3. The key regions KR may include key structures described below. The key structure may include an overlay key, an alignment key, or a combination thereof, and different ones of the first to third key regions KR1, KR2, and KR3 may independently include different ones of an overlap key, an alignment key, or a combination thereof. The key regions KR may include dummy elements that are electrically non-functional elements in the semiconductor device 10.

Hereinafter, some example embodiments of the first to fifth circuit regions CR1, CR2, CR3, CR4, and CR5 and the key regions KR may be described.

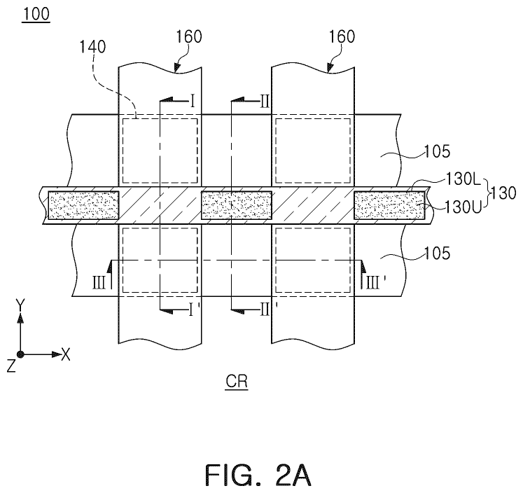

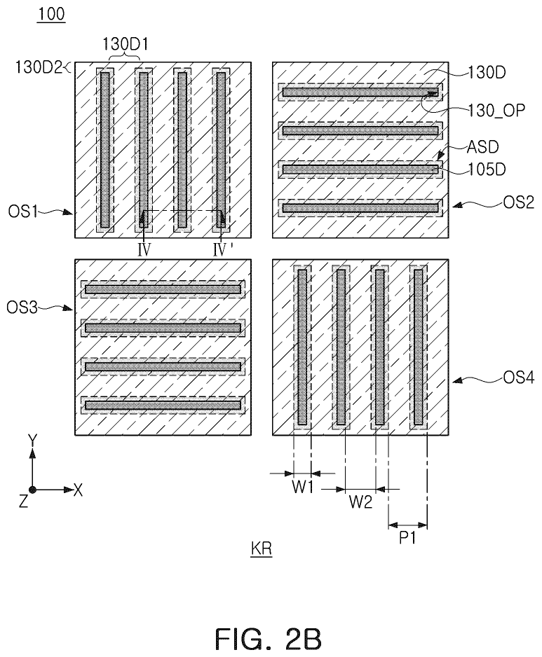

FIGS. 2A and 2B are plan views illustrating a semiconductor device according to example embodiments. For ease of description, only a portion of elements of the semiconductor device are illustrated in FIGS. 2A and 2B.

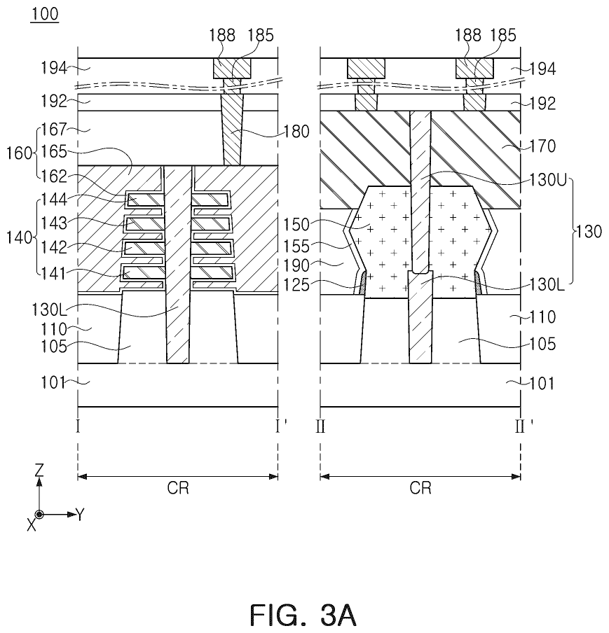

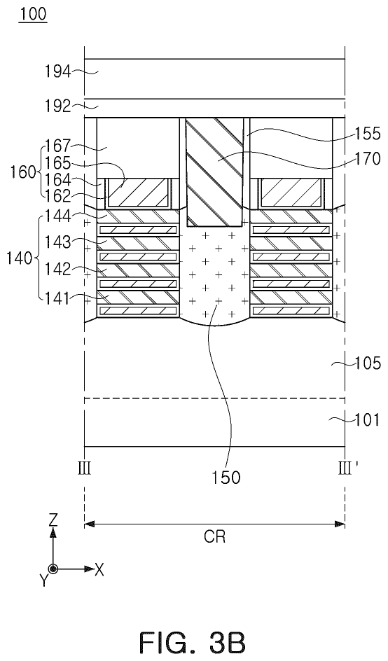

FIGS. 3A and 3B are cross-sectional views illustrating a semiconductor device according to example embodiments. FIG. 3A illustrates a cross-sectional of the semiconductor device in FIG. 2A taken along lines I-I′ and II-II′, and FIG. 3B illustrates a cross-sectional of the semiconductor device in FIG. 2A taken along lines III-III′.

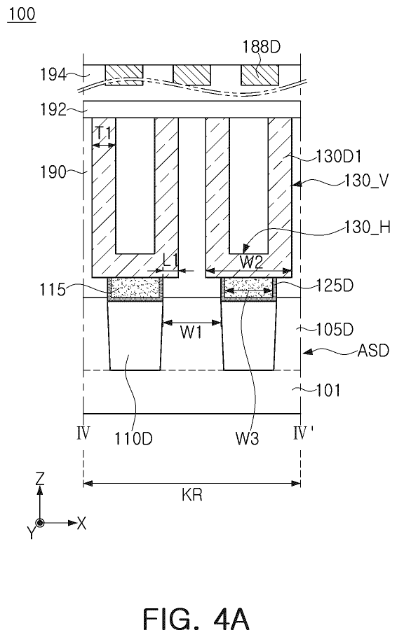

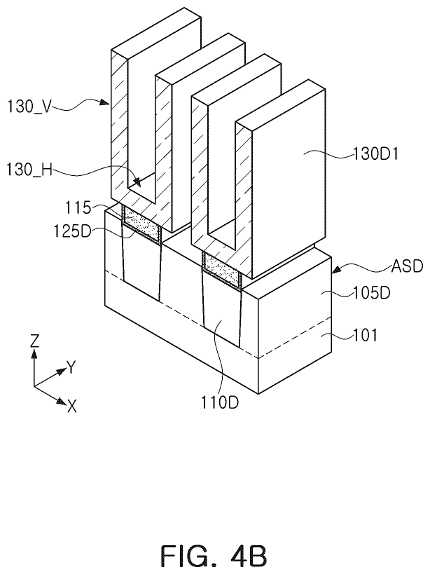

FIGS. 4A and 4B are a cross-sectional view and a perspective view illustrating a semiconductor device according to example embodiments. FIG. 4A may illustrate a cross-sectional of the semiconductor device in FIG. 2B taken along lines IV-IV′, and FIG. 4B is a perspective view illustrating a region including the cross-sectional region in FIG. 4A.

Referring to FIGS. 2A to 4B, the semiconductor device 100 may include a substrate 101 including a circuit region CR and a key region KR. The circuit region CR may correspond to one or more of the first to fifth circuit regions CR1, CR2, CR3, CR4, and CR5 in FIG. 1, and the key region KR may correspond to one or more of the first to third key regions KR1, KR2, and KR3 in FIG. 1.

Referring to FIGS. 2A, 3A, and 3B, the circuit region CR may include active regions 105 on a substrate 101, channel structures 140 vertically disposed and spaced apart from each other on the active regions 105 and including first to fourth channel layers 141, 142, 143, and 144, gate structures 160 extending by intersecting the active regions 105 and including gate electrodes 165, source/drain regions 150 in contact with the channel structures 140, isolation structures 130 between adjacent source/drain regions 150, source contact plugs 170 connected to the source/drain regions 150, and gate contact plugs 180 connected to the gate electrodes 165. The circuit region CR may further include a device isolation layer 110, sidewall spacer layers 125, insulating liner layers 155, upper contacts 185, upper interconnection lines 188 and first to third interlayer insulating layers 190, 192, and 194.

In the circuit region CR, the active regions 105 may have a fin structure, and the gate electrodes 165 may be disposed between the active regions 105 and the channel structure 140, between the first to fourth channel layers 141, 142, 143, and 144 of the channel structure 140, and on the channel structure 140. Accordingly, the circuit region CR may include transistors of a multi-bridge channel FET (MBCFET™) structure, which is a gate-all-around type field effect transistor.

The substrate 101 may have an upper surface extending in an X-direction and a Y-direction. The substrate 101 may include a semiconductor material, such as one or more of a group IV semiconductor, a group III-V compound semiconductor, or a group II-VI compound semiconductor. For example, the group IV semiconductor may include one or more of silicon, germanium, or silicon-germanium. The substrate 101 may be provided as a bulk wafer, an epitaxial layer, a silicon on insulator (SOI) layer, or a semiconductor on insulator (SeOI) layer. The substrate 101 may or may not be doped with impurities, such as P-type impurities including boron; example embodiments are not limited thereto.

The substrate 101 may include a circuit region CR and a key region KR, and the circuit region CR and the key region KR may be adjacent to each other or spaced apart from each other as described above with reference to FIG. 1. The circuit region CR and the key region KR may also be referred to as regions of the semiconductor device 100, not regions of the substrate 101.

The active regions 105 may be defined by the device isolation layer 110 on the substrate 101 and may extend in the first direction, for example, in the X-direction. Depending on descriptions, the active regions 105 may be described as being a portion of the substrate 101. The active regions 105 may partially protrude to the device isolation layer 110 below the gate structures 160, such that a portion of upper surfaces of the active regions 105 are positioned at a level higher than a level of an upper surface of the device isolation layer 110. The active regions 105 may be formed as a portion of the substrate 101 and/or may include an epitaxial layer grown from the substrate 101. There may or may not be a seem or an interface between the active regions 105 and the substrate 101. The active regions 105 may be partially recessed on both sides of the gate structures 160 such that recess regions may be formed, and the source/drain regions 150 may be disposed in the recess regions.

Each of the active regions 105 may include a well region including impurities. For example, the well region may include p-type impurities, such as one or more of boron (B), gallium (Ga), or aluminum (Al), or n-type impurities, such as phosphorus (P), arsenic (As), or antimony (Sb). In some example embodiments the well region may be counterdoped and may include both p-type impurities and n-type impurities, with a concentration of a first conductivity type among p-type and n-type impurities greater than, e.g., much greater than, a concentration of a second conductivity type among p-type and n-type impurities; example embodiments are not limited thereto. The well region may be positioned at a depth such as a predetermined depth from an upper surface of each of the active regions 105, for example. The depth may be determined based on an energy of an ion implantation process used to form the well region; example embodiments are not limited thereto.

The device isolation layer 110 may define active regions 105 on the substrate 101. The device isolation layer 110 may be formed, for example, by a shallow trench isolation (STI) process including but not limited to a plasma enhanced chemical vapor deposition (PECVD) process and/or a spin-on dielectric (SOD) process; example embodiments are not limited thereto. The device isolation layer 110 may expose at least upper surfaces of the active regions 105, and may also expose a portion of an upper portion. In some example embodiments, the device isolation layer 110 may have a curved upper surface having a level increasing toward the active regions 105. The device isolation layer 110 may be formed of an insulating material. The device isolation layer 110 may be, for example, oxide, nitride, or a combination thereof.

The gate structures 160 may extend in one direction, for example, in the Y-direction, on the active regions 105. A lower isolation structure 130L of the device isolation structure 130 may be interposed between adjacent gate structures 160 in the Y-direction. Channel regions of transistors may be formed in the channel structures 140 intersecting the gate electrodes 165 of the gate structures 160. The gate structures 160 may be spaced apart from each other in the X-direction. Each of the gate structures 160 may include gate dielectric layers 162, gate spacer layers 164, a gate electrode 165, and a gate capping layer 167.

The gate dielectric layers 162 may be disposed between the active region 105 and the gate electrode 165 and between the channel structure 140 and the gate electrode 165, and may be disposed to cover at least a portion of surfaces of the gate electrode 165. For example, the gate dielectric layers 162 may be disposed to surround the entirety of surfaces other than an uppermost surface of the gate electrode 165. The gate dielectric layers 162 may extend between the gate electrode 165 and the gate spacer layers 164, but example embodiments are not limited thereto. The gate dielectric layers 162 may also extend to a side surface of the lower isolation structure 130L. The gate dielectric layers 162 may include one or more of oxide, nitride, or a high-κ material. The high-κ material may indicate a dielectric material having a higher dielectric constant than silicon oxide (SiO₂). The high-κ material may be a dielectric material having a dielectric constant higher than that of silicon oxide (SiO₂). The high-κ material may be or include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). According to some example embodiments, the gate dielectric layer 162 may be formed as a multilayer structure.

The gate electrode 165 may include a conductive material, for example, a metal nitride such as one or more of titanium nitride (TiN), tantalum nitride (TaN), or tungsten nitride (WN), and/or a metal material such as aluminum (Al), tungsten (W), or molybdenum (Mo), or a semiconductor material such as doped polysilicon. In some example embodiments, the gate electrode 165 may be formed as a multilayer structure. The gate electrodes 165 may be connected to the gate contact plugs 180.

The gate spacer layers 164 may be disposed on both side surfaces of the gate electrodes 165 on the channel structure 140. The gate spacer layers 164 may insulate the source/drain regions 150 and the gate electrodes 165. In some example embodiments, a shape of an upper end of the gate spacer layers 164 may be varied, and the gate spacer layers 164 may be formed as a multilayer structure. The gate spacer layers 164 may include at least one of oxide, nitride, or oxynitride, and may be formed of, for example, a low-κ film.

The gate capping layers 167 may be disposed on the gate structure 160. In some example embodiments, a lower surface of the gate capping layer 167 may have a downwardly curved shape. The gate capping layer 167 may include an insulating material, for example, at least one of oxide, nitride, or oxynitride.

The channel structures 140 may include a number of channel layers such as first to fourth channel layers 141, 142, 143, and 144, a plurality of two or more channel layers spaced apart from each other in a direction perpendicular to an upper surface of each of the active regions 105, for example in the Z-direction, on each of the active regions 105. The first to fourth channel layers 141, 142, 143, and 144 may be connected to the source/drain regions 150, and may be spaced apart from an upper surface of the active regions 105. The first to fourth channel layers 141, 142, 143, and 144 may have the same width or similar widths in the Y-direction as the active regions 105, and may have the same or similar width in the X-direction as the gate structures 160. Widths in the Y-direction of the first to fourth channel layers 141, 142, 143, 144 may increase toward a lower channel layer, but example embodiments are not limited thereto. The number of the channel layers 141, 142, 143, and 144 of each of the channel structures 140 and/or the shape and/or thickness thereof may be varied in example embodiments.

A lower isolation structure 130L may be interposed between adjacent channel structures 140 in the Y-direction. Side surfaces of the channel layers 141, 142, 143, and 144 in the Y-direction may be in contact with the lower isolation structure 130L, and the other side surfaces may protrude into the gate electrodes 165.

The first to fourth channel layers 141, 142, 143, and 144 may be formed of a semiconductor material, for example, including at least one of silicon (Si), silicon germanium (SiGe), or germanium (Ge). The first to fourth channel layers 141, 142, 143, and 144 may be formed of the same material as a material of the substrate 101, for example.

The source/drain regions 150 may be disposed on both sides of the gate structures 160, respectively, so as to be in contact with the channel structures 140. The source/drain regions 150 may be disposed to cover side surfaces of the first to fourth channel layers 141, 142, 143, and 144 of the channel structure 140 in the X-direction, respectively. Upper surfaces of the source/drain regions 150 may be positioned at a level the same as or higher than a level of a lower surface of the gate electrode 165 on the channel structure 140, and the level may be varied in example embodiments.

At least an upper region of the source/drain regions 150 may have a polygonal shape in a cross-sectional view in the Y-direction on an outer side of the gate structures 160. In some example embodiments, the shape of the upper region is not limited to the shape illustrated in FIG. 3A, and may have various other shapes such as but not limited to a curved polygonal shape, an elliptical shape, or a circular shape. At least a portion of side surfaces of the lower region of the source/drain regions 150 may be covered by sidewall spacer layers 125. An upper region of the source/drain regions 150 may be covered by an insulating liner 155. The source/drain regions 150 may be connected to the source contact plugs 170, respectively.

The source/drain regions 150 may include at least one of a semiconductor material, for example, silicon (Si) or germanium (Ge), and may further include impurities such as n-type impurities and/or p-type impurities. Each of the source/drain regions 150 may include a plurality of epitaxial layers having different compositions.

In some example embodiments, the circuit region CR may further include internal spacer layers disposed between side surfaces of the source/drain regions 150 in the X-direction and the gate dielectric layers 162. The internal spacer layers may include an insulating material.

The sidewall spacer layers 125 may be disposed on the device isolation layer 110 on an outer side of the gate structures 160. The sidewall spacer layers 125 may cover both side surfaces in the Y-direction of the lower regions of the source/drain regions 150. The sidewall spacer layers 125 may include an insulating material, and may include at least one of oxide, nitride, or oxynitride.

The source contact plugs 170 may be connected to the upper region of the source/drain regions 150 and may apply an electrical signal to the source/drain regions 150. The source contact plugs 170 may penetrate the insulating liners 155 and the first interlayer insulating layer 190. The source contact plugs 170 may have an inclined side surface such that a width of a lower portion may be narrower than a width of an upper portion depending on an aspect ratio, but example embodiments are not limited thereto. The source contact plugs 170 may be recessed into the second source/drain regions 150 from upper surfaces of the second source/drain regions 150. The source contact plugs 170 may extend further below a lower surface of the fourth channel layer 144 of the uppermost portion of the channel structure 140 from an upper portion, but example embodiments are not limited thereto.

The gate contact plug 180 may penetrate the second interlayer insulating layer 192 and the gate capping layer 167 and may be connected to the gate electrode 165.

The source contact plugs 170 and the gate contact plug 180 may include a conductive material, for example, a metal material such as at least one of aluminum (Al), tungsten (W), or molybdenum (Mo). According to some example embodiments, the source contact plug 170 may include a metal-semiconductor compound layer, for example, a metal silicide layer, positioned at an interfacial surface with the source/drain region 150, and may further include a barrier layer forming side surfaces of the source contact plugs 170 and extending to an upper surface of the metal-semiconductor compound layer. Similarly, the gate contact plug 180 may include a metal-semiconductor compound layer, for example, a metal silicide layer, positioned at an interfacial surface with the gate electrode 165, and may further include a barrier layer forming side surfaces of the gate contact plug 180 and extending to an upper surface of the metal-semiconductor compound layer. The barrier layer may include, for example, a metal nitride, such as one or more of titanium nitride (TiN), tantalum nitride (TaN), or tungsten nitride (WN).

The isolation structures 130 may have a line shape extending in the X-direction as illustrated in FIG. 2A, and may be interposed between adjacent gate structures 160, between channel structures 140, between active regions 105, and between source/drain regions 150 in the Y-direction. The isolation structure 130 may include a lower isolation structure 130L and an upper isolation structure 130U on the lower isolation structure 130L. The lower isolation structure 130L may extend continuously in the X-direction, and the upper isolation structure 130U may be disposed only on an outer side of the gate structures 160 in the X-direction. A width of the upper isolation structure 130U is illustrated as being smaller than a width of the lower isolation structure 130L, but example embodiments are not limited thereto, and the width may be the same as or greater than a width of the lower isolation structure 130L.

An upper surface of the lower isolation structure 130L may be positioned at substantially the same level as an upper surface of the gate electrodes 165 between the gate structures 160. In some example embodiments, an upper surface of the lower isolation structure 130L may be positioned at a level the same as or similar to a level of an upper surface of the fourth channel layer 144 in an uppermost portion. In this case, another gate isolation structure may be disposed on the lower isolation structure 130L to isolate the gate electrodes 165. The lower isolation structure 130L may have an inclined side surface of which a width may decrease toward the substrate 101, but the shape of the side surface of the lower isolation structure 130L is not limited thereto.

An upper surface of the lower isolation structure 130L may be disposed to have a relatively small height on an outer side of the gate structures 160. The upper surface of the lower isolation structure 130L may be positioned in the source/drain region 150. For example, the upper surface of the lower isolation structure 130L may be positioned at substantially the same level as a level of upper ends of the sidewall spacer layers 125, but example embodiments are not limited thereto.

The upper isolation structure 130U may be disposed between the source/drain regions 150 on an outer side of the gate structures 160 and connected to the lower isolation structure 130L. The upper isolation structure 130U may be disposed between adjacent source contact plugs 170 in the Y-direction. The upper surface of the upper isolation structure 130U may be positioned at substantially the same level as upper surfaces of the source contact plugs 170, but example embodiments are not limited thereto.

The isolation structures 130 may include an insulating material, for example, a material different from a material of the device isolation layer 110. The isolation structures 130 may include, for example, at least one of silicon nitride or silicon oxynitride. For example, the lower isolation structure 130L and the upper isolation structure 130U may include the same or different material.

A first interlayer insulating layer 190 may cover the source/drain regions 150. A second interlayer insulating layer 192 may cover the gate structures 160 and the source contact plugs 170. A third interlayer insulating layer 194 may be disposed on the second interlayer insulating layer 192. The first to third interlayer insulating layers 190, 192, and 194 may include at least one of an insulating material, such as oxide, nitride, and oxynitride, and may include, for example, a low-κ material; the first to third interlayer insulating layers 190, 192, and 194 may include the same and/or different materials. In example embodiments, at least one of the first to third interlayer insulating layers 190, 192, or 194 may include a plurality of insulating layers.

The upper contacts 185 may electrically connect the source contact plugs 170 and the gate contact plug 180 to the upper interconnection lines 188. The upper contacts 185 and the upper interconnection lines 188 may be disposed to form a plurality of layers, respectively. The upper contacts 185 and the upper interconnection lines 188 may include at least one of a conductive material, for example, tungsten (W), copper (Cu), aluminum (Al), cobalt (Co), ruthenium (Ru), titanium (Ti), or molybdenum (Mo). The upper contacts 185 and the upper interconnection lines 188 may be disposed in a plurality of layers.

Referring to FIGS. 2B, 4A, and 4B, the key region KR may include dummy active regions 105D on the substrate 101, dummy device isolation layer 110D defining the dummy active regions 105D in the substrate 101, dummy upper isolation structures 130D on the dummy active regions 105D and dummy device isolation layer 110D, mask insulating layers 115 between the dummy device isolation layer 110D and the dummy upper isolation structures 130D, and dummy sidewall spacer layers 125D on lower surfaces and side surfaces of the mask insulating layers 115. The key region KR may further include dummy upper interconnection lines 188D and first to third interlayer insulating layers 190, 192, and 194.

As illustrated in FIG. 2B, the key region KR may include first to fourth key structures OS1, OS2, OS3, and OS4 arranged to form a rectangle. The first key structure OS1 and the second key structure OS2 may be arranged in the X-direction, the third key structure OS3 may be arranged in the Y-direction with the first key structure OS1, and the fourth key structure OS4 may be arranged in the X-direction with the third key structure OS3. The first and fourth key structures OS1 and OS4 may have the same structure, and the second and third key structures OS2 and OS3 may have the same structure. For example, the first to fourth key structures OS1, OS2, OS3, and OS4 may be used to measure an overlay between the dummy active regions 105D and the dummy upper isolation structures 130D. For example, the first and fourth key structures OS1 and OS4 may measure an alignment in the X-direction, and the second and third key structures OS2 and OS3 may measure alignment in the Y-direction.

In plan view, each of the first and fourth key structures OS1 and OS4 may include dummy active structures ASD in the form of lines extending in the Y-direction, and dummy upper isolation structure 130D alternately disposed with the dummy active structures ASD in the X-direction and having ends, in the Y-direction, connected each other. The dummy upper isolation structure 130D may include first patterns 130D1 alternately disposed with the dummy active structures ASD and extending in the Y-direction, and second patterns 130D2 connecting ends of the first patterns 130D1 to each other. The dummy upper isolation structure 130D may overlap edge regions of each of the dummy active structures ASD and may be disposed as a single layer. The second and third key structures OS2 and OS3 may have structures formed by rotating the first and fourth key structures OS1 and OS4 by 90 degrees. Accordingly, in each of the second and third key structures OS2 and OS3, the extension direction of the dummy active structures ASD may be in the X-direction.

In each of the first to fourth key structures OS1, OS2, OS3, and OS4, the dummy upper isolation structure 130D may have openings 130_OP exposing the dummy active structures ASD, and may have a lattice shape or a mesh shape. In plan view, the dummy active structures ASD may be exposed through entire regions of the openings 130_OP. In FIG. 2B, a length by which the dummy upper isolation structure 130D overlaps the dummy active structures ASD in the Z-direction is illustrated as being constant, but example embodiments are not limited thereto. For example, a length by which the dummy upper isolation structure 130D overlaps at an edge in the extension direction of the dummy active structures ASD may be greater than a length by which the dummy upper isolation structure 130D overlaps at an edge in the direction perpendicular to the extension direction.

Each of the dummy active structures ASD may include, for example, a single dummy active region 105D. The first width W1 of the dummy active structure ASD or the dummy active region 105D may be the same as or smaller than the second width W2 of the first patterns 130D1. The length from one end of the dummy active structure ASD to one end of the adjacent dummy active structure ASD, that is, the pitch P1, may be in a range of about 500 nm to about 700 nm.

The dummy active regions 105D may be formed together with the active regions 105 of the circuit region CR, and unless otherwise indicated, the description of the active regions 105 may be also applied to the dummy active regions 105D. The dummy device isolation layer 110D may be formed with the device isolation layer 110 of the circuit region CR, and may define the dummy active regions 105D. In some example embodiments, relative widths of the dummy active regions 105D and the active regions 105 may be varied.

The dummy sidewall spacer layers 125D may be formed together with the sidewall spacer layers 125 of the circuit region CR. The dummy sidewall spacer layers 125D may cover an upper surface of the dummy device isolation layer 110D and may extend horizontally, and may extend vertically to cover side surfaces of the mask insulating layers 115. Upper ends of the dummy sidewall spacer layers 125D may be positioned at a level the same as or similar to a level of upper ends of the sidewall spacer layers 125.

The mask insulating layers 115 may be disposed between the dummy device isolation layer 110D and the dummy upper isolation structure 130D. The entire upper surfaces of the mask insulating layers 115 may be covered with the dummy upper isolation structure 130D, and side surfaces may be covered with the dummy sidewall spacer layers 125D.

The dummy upper isolation structure 130D may be disposed on a portion of each of the dummy active structures ASD and the dummy device isolation layer 110D. The first patterns 130D1 of the dummy upper isolation structure 130D may overlap the entire dummy device isolation layer 110D in the Z-direction between the dummy active structures ASD. Each of the first and second patterns 130D1 and 130D2 of the dummy upper isolation structure 130D may be disposed on the mask insulating layer 115, and the first patterns 130D1 may overlap the dummy active regions 105D on both sides in the Z-direction. Each of the first and second patterns 130D1 and 130D2 may have a width greater than a width of the upper isolation structure 130U, and accordingly, each of the first and second patterns 130D1 and 130D2 may have a U-shape or a shape similar thereto. As illustrated in FIGS. 4A and 4B, the dummy upper isolation structure 130D may extend with a uniform thickness T1, and at least each of the first patterns 130D1 may include two vertical portions 130_V spaced apart from each other in a direction perpendicular to the extension direction and a horizontal portion 130_H connecting the two vertical portions 130_V to each other in a lower portion. A thickness T1 of the dummy upper isolation structure 130D may be greater than half the width of the upper isolation structure 130U of the circuit region CR.

Each of the first and second patterns 130D1 and 130D2 may be disposed on the mask insulating layer 115 with a second width W2 greater than a third width W3 of the mask insulating layer 115. Accordingly, the dummy upper isolation structure 130D may cover the entire upper surface of the mask insulating layer 115. The dummy upper isolation structure 130D may also cover upper surfaces of the dummy sidewall spacer layers 125D. In some example embodiments, the second width W2 of the first and second patterns 130D1 and 130D2 may be the same as the third width W3 of the mask insulating layer 115. Even in this case, the dummy upper isolation structure 130D may cover the entire upper surface of the mask insulating layer 115. A spacing between the first patterns 130D1 may be the same as or less than the second width W2.

The dummy upper isolation structure 130D may be formed with the upper isolation structure 130U of the circuit region CR and may include the same material as the upper isolation structure 130U. At least a portion of the dummy upper isolation structure 130D may be positioned at the same level as the upper isolation structure 130U. For example, a lower end of the dummy upper isolation structure 130D may be positioned at a level the same as or similar to a lower end of the dummy upper isolation structure 130D, and an upper end of the dummy upper isolation structure 130D may be positioned at a level the same as or similar to a level of an upper end of the dummy upper isolation structure 130D.

In some example embodiments, the dummy upper isolation structure 130D may cover the entire upper surface of the mask insulating layer 115. Also, in each of the first to fourth key structures OS1, OS2, OS3, and OS4, ends of the first patterns 130D1 of the dummy upper isolation structure 130D may be connected to the second patterns 130D2 and may be disposed as an integrated layer. Accordingly, the removal of the mask insulating layer 115 and lifting of the dummy upper isolation structure 130D may be prevented or reduced in likelihood of occurrence and/or in impact from occurrence, during a process of manufacturing the semiconductor device 100, and the dummy upper isolation structure 130D may stably remain in the key region KR.

The first interlayer insulating layer 190 may cover the upper isolation structure 130U. In some example embodiments, the key region KR may further include an insulating layer disposed on the upper isolation structure 130U and formed in a process different from a process of forming the first interlayer insulating layer 190. In some example embodiments, the first interlayer insulating layer 190 may further include air gap regions positioned between the vertical portions 130_V.

The dummy upper interconnection lines 188D may be formed together with the upper interconnection lines 188 of the circuit region CR, may be disposed in the third interlayer insulating layer 194 and may not perform substantial electrical functions in the semiconductor device 100.

In the description in the example embodiments below, the description overlapping the description described above with reference to FIGS. 2A to 4B may not be provided.

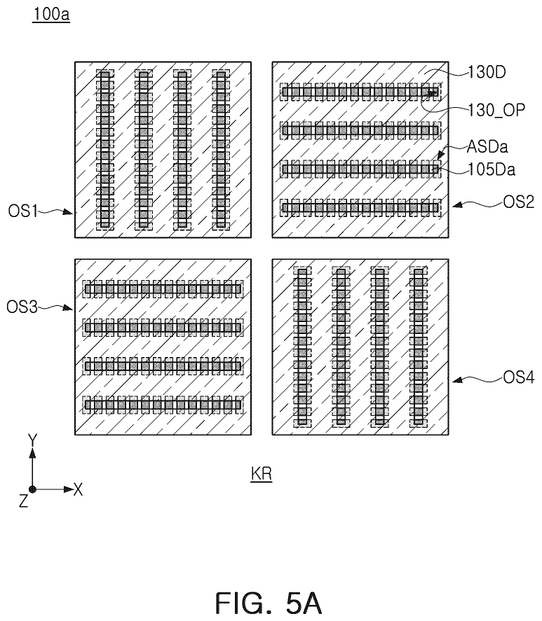

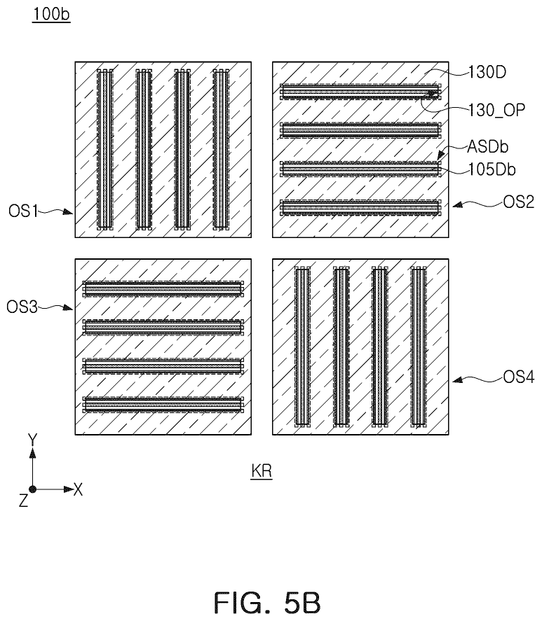

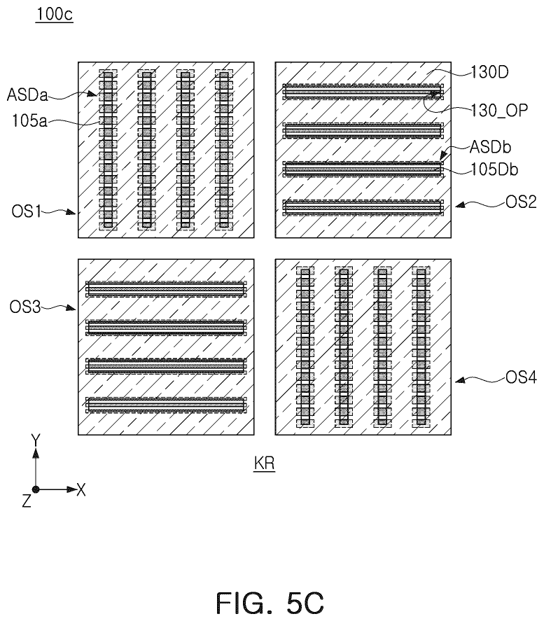

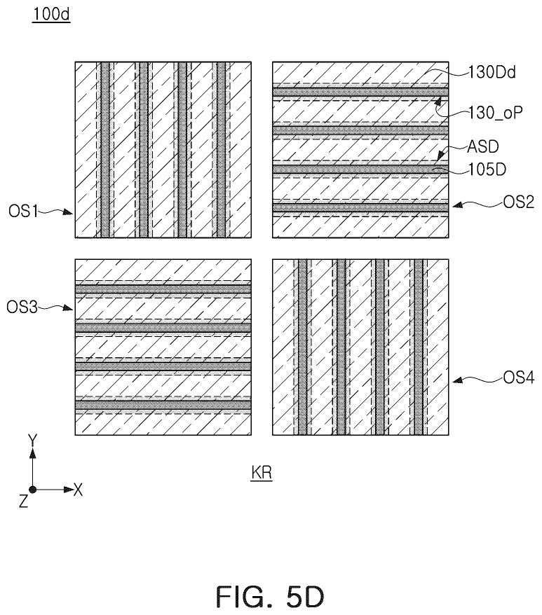

FIGS. 5A to 5D are plan views illustrating a semiconductor device according to some example embodiments, illustrating a region corresponding to FIG. 2B.

Referring to FIG. 5A, in the key region KR of the semiconductor device 100a, each of the dummy active structures ASDa may include a plurality of dummy active regions 105Da. The dummy active regions 105Da included in the dummy active structure ASDa may have a rectangular shape extending in a direction perpendicular to the extension direction of the dummy active structure ASDa. The dummy active regions 105Da may be spaced apart from each other in the extension direction. The dummy upper isolation structure 130D may overlap edge regions in at least one direction of the dummy active regions 105Da. In example embodiments, the width and the number of the dummy active regions 105Da included in each dummy active structure ASDa may be varied.

Referring to FIG. 5B, in the key region KR of the semiconductor device 100b, each of the dummy active structures ASDb may include a plurality of dummy active regions 105Db. The dummy active regions 105 Db included in the dummy active structure ASDb may have a rectangular shape extending in the extension direction of the dummy active structure ASDb. The dummy active regions 105Db may be spaced apart from each other in a direction perpendicular to the extension direction. The dummy upper isolation structure 130D may overlap edge regions in at least one direction of the dummy active regions 105Db. In example embodiments, the width and the number of the dummy active regions 105Db included in each dummy active structure ASDb may be varied.

Referring to FIG. 5C, in the key region KR of the semiconductor device 100c, the first and fourth key structures OS1 and OS4 may include dummy active structures ASDa in the example embodiment in FIG. 5A, and the second and third key structures OS2 and OS3 may include dummy active structures ASDb in the example embodiment in FIG. 5B.

As described above, in the example embodiments, key structures in different example embodiments may be combined in various manners in the range in which the first and fourth key structures OS1 and OS4 have the same structure and the second and third key structures OS2 and OS3 have the same structure.

Referring to FIG. 5D, in the key region KR of the semiconductor device 100D, each of the first to fourth key structures OS1, OS2, OS3, and OS4 may include a plurality of dummy upper isolation structures 130Dd. In each of the first to fourth key structures OS1, OS2, OS3, and OS4, the dummy upper isolation structures 130Dd may be arranged alternately in one direction with the dummy active structures ASD, and may overlap edge regions of the dummy active structures ASD.

In the example embodiment, the first to fourth key structures OS1, OS2, OS3, and OS4 may not include the second patterns 130D2 in FIG. 2B. Even in this case, as described above, since the plurality of dummy upper isolation structures 130Dd may overlap a portion of each of the dummy active structures ASD, the lifting defect of the plurality of dummy upper isolation structures 130Dd may be prevented or reduced in likelihood of occurrence and/or in impact from occurrence.

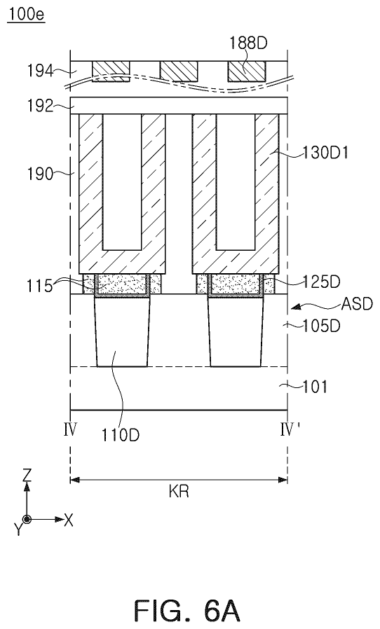

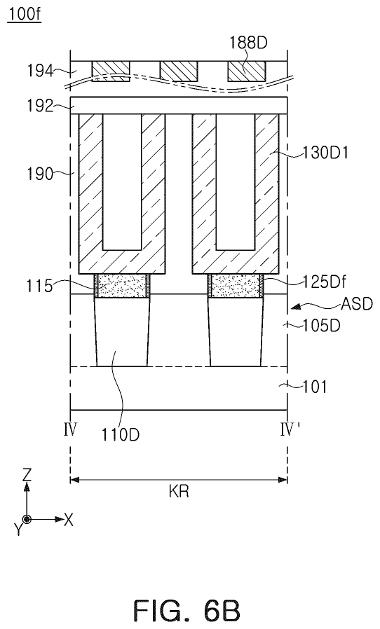

FIGS. 6A and 6B are cross-sectional views illustrating a semiconductor device according to some example embodiments, illustrating regions corresponding to FIG. 4A.

Referring to FIG. 6A, in the key region KR of the semiconductor device 100e, the mask insulating layers 115 may be disposed further on outer side surfaces of the dummy sidewall spacer layers 125D between the dummy device isolation layer 110D and the dummy upper isolation structure 130D. A thickness and/or a shape of the mask insulating layers 115 remaining on the outer side surfaces of the dummy sidewall spacer layers 125D may be varied in some example embodiments.

Referring to FIG. 6B, in the key region KR of the semiconductor device 100f, the dummy sidewall spacer layers 125Df may not cover an upper surface of the dummy device isolation layer 110D and may include only vertical regions. The dummy sidewall spacer layers 125Df may cover side surfaces of the mask insulating layer 115, respectively and may be spaced apart from each other. The structure described above may be due to, for example, changing the process for the key region KR in the process of manufacturing the semiconductor device 100f.

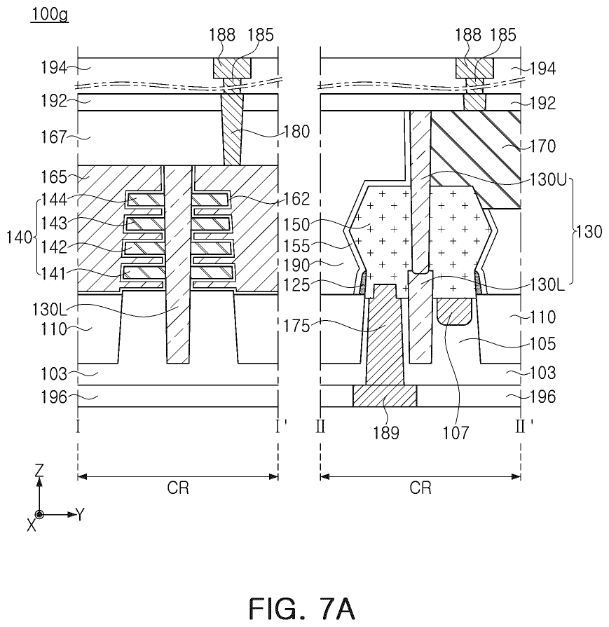

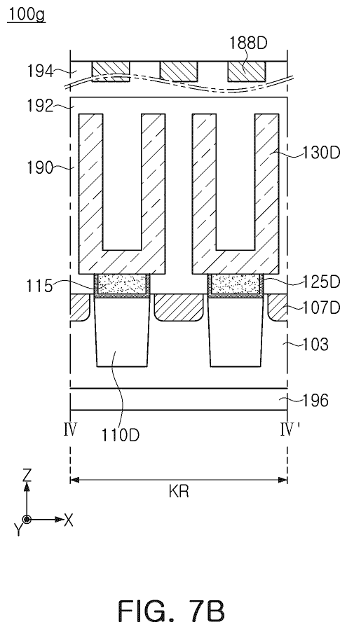

FIGS. 7A and 7B are cross-sectional views illustrating a semiconductor device according to some example embodiments. FIG. 7A may illustrate a region corresponding to FIG. 3A, and FIG. 7B may illustrate a region corresponding to FIG. 4A.

Referring to FIGS. 7A and 7B, a semiconductor device 100g may not include a substrate 101, active regions 105, and a dummy active regions 105D, and may further include a substrate insulating layer 103, a backside insulating layer 196, a backside contact plug 175, a backside interconnection line 189, an epitaxial layer 107, and dummy epitaxial layers 107D.

The substrate insulating layer 103 may be formed by removing and/or oxidizing (e.g., thermally oxidizing) the substrate 101, the active regions 105, and the dummy active regions 105D, which may be formed of a semiconductor material, during the manufacturing process. The backside insulating layer 196 may be disposed on a lower surface of the substrate insulating layer 103. The substrate insulating layer 103 and the backside insulating layer 196 may be formed of the same or different insulating material, and may include, for example, oxide, nitride, or a combination thereof. In example embodiments, at least one of the substrate insulating layer 103 and the backside insulating layer 196 may include a plurality of insulating layers.

The backside contact plug 175 may penetrate the substrate insulating layer 103 and may be connected to a lower surface of at least one of the source/drain regions 150. The backside contact plug 175 may be partially recessed into the source/drain region 150 from a lower surface. The backside interconnection line 189 may be disposed in the backside insulating layer 196 and may be connected to the backside contact plug 175. The backside interconnection line 189, together with the backside contact plug 175, may form a backside power delivery network (BSPDN) applying power or ground voltage. The backside contact plug 175 and the backside interconnection line 189 may include a conductive material, for example, a metal material such as at least one of aluminum (Al), tungsten (W), or molybdenum (Mo).

The epitaxial layer 107 and the dummy epitaxial layers 107D may be disposed in regions partially recessed into the active region 105 and the dummy active regions 105D, respectively. The epitaxial layer 107 may be used in forming the backside contact plug 175. The dummy epitaxial layers 107D may be formed together with the epitaxial layer 107. The epitaxial layer 107 may be in contact with a lower surface of the source/drain region 150. Upper surfaces of the dummy epitaxial layers 107D may be covered with a first interlayer insulating layer 190. The epitaxial layer 107 and the dummy epitaxial layers 107D may include at least one of a semiconductor material, for example, silicon (Si) or germanium (Ge), and may have a composition different from that of the source/drain regions 150. In some example embodiments, the epitaxial layer 107 and the dummy epitaxial layer 107D may include the same or different material, at the same or different compositions, and in some example embodiments either or both of the epitaxial layer 107 and the dummy epitaxial layer 107D may be doped with impurities.

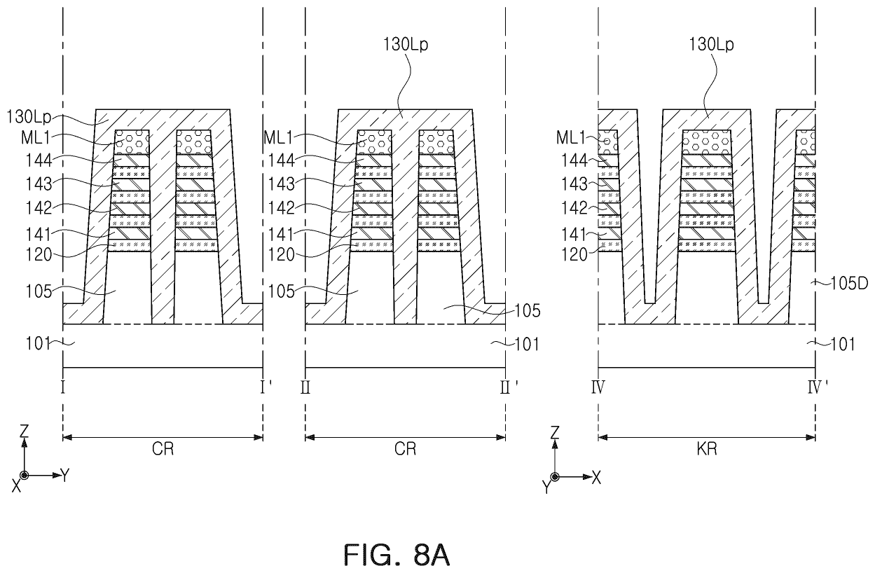

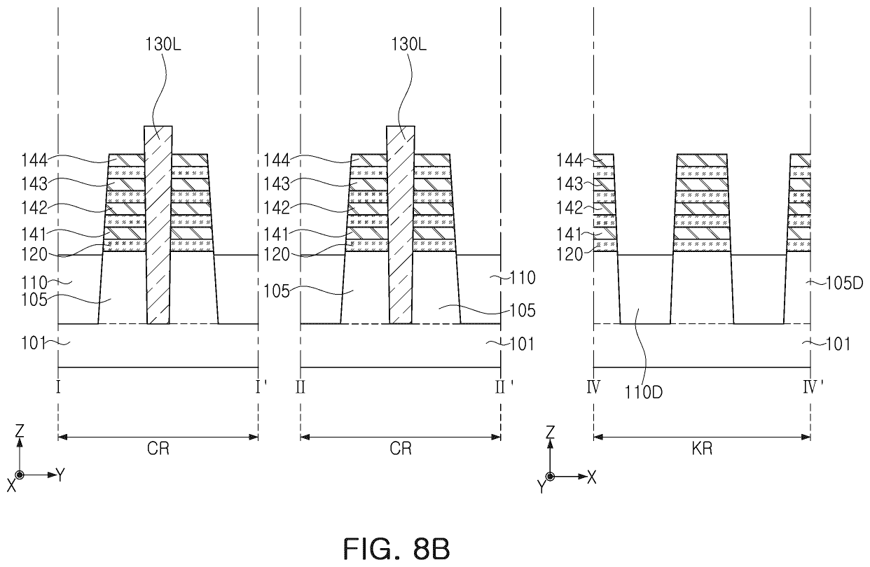

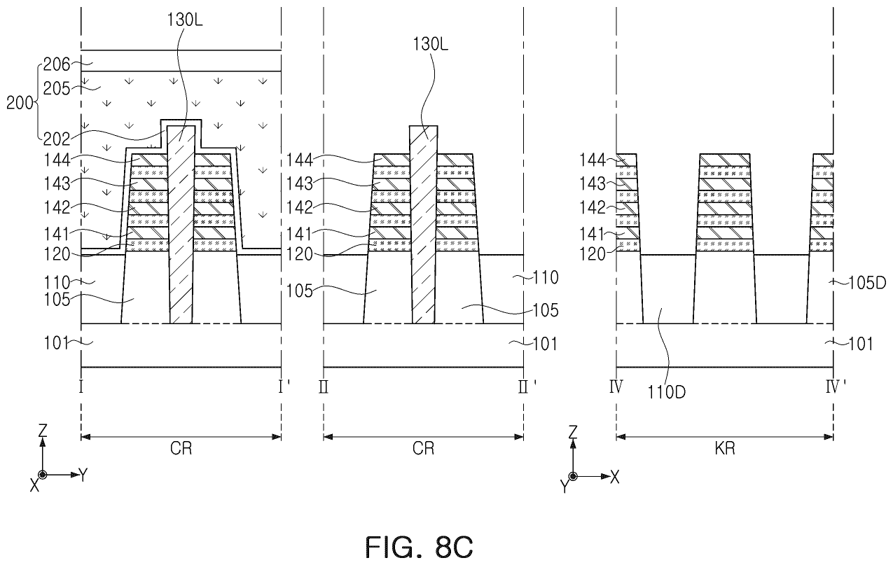

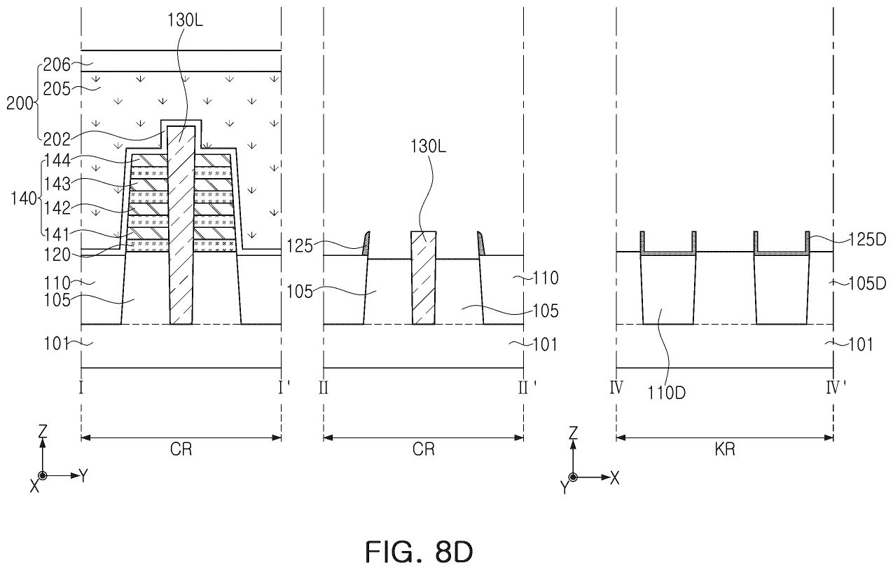

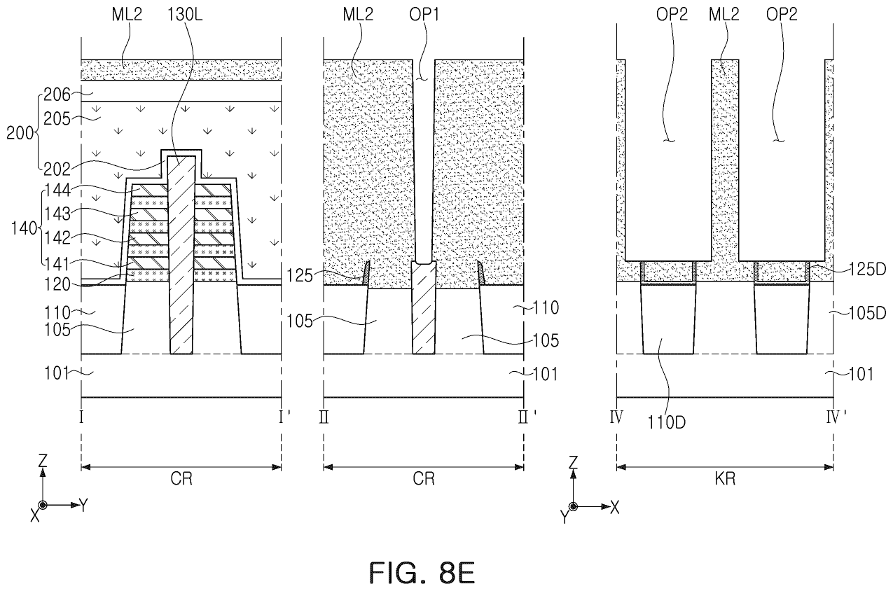

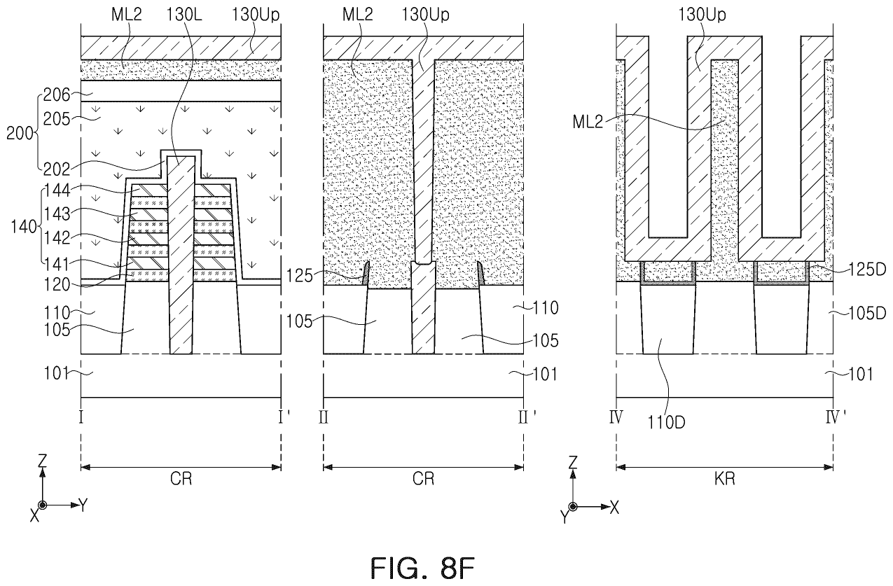

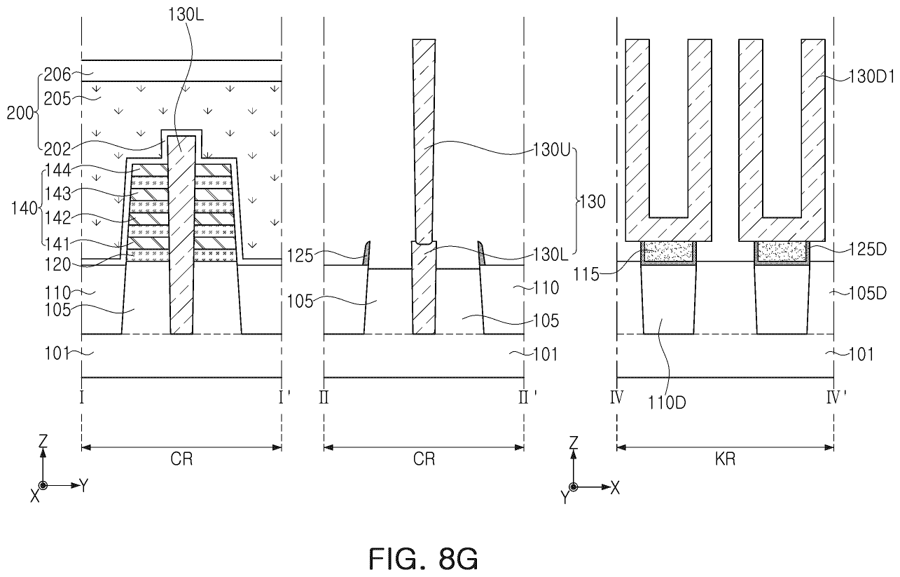

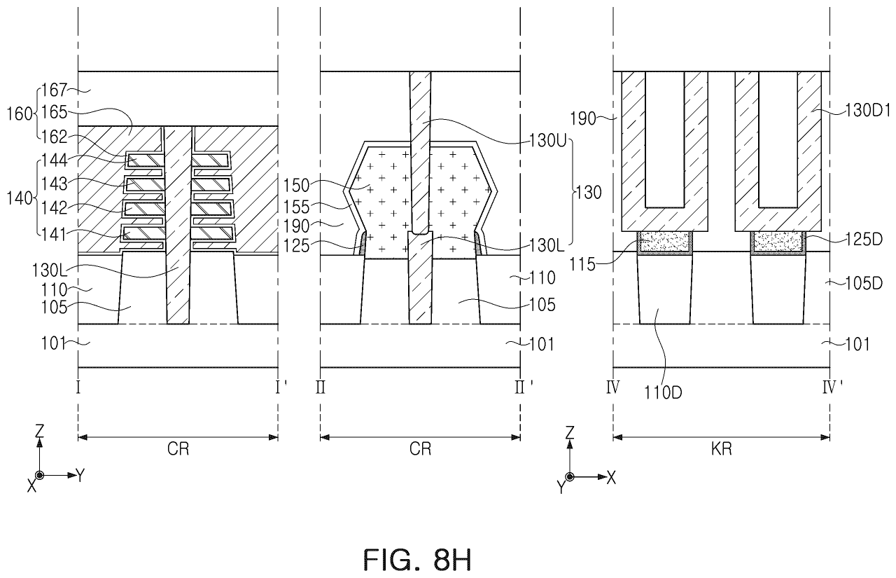

FIGS. 8A to 8H are views illustrating processes of a method of manufacturing a semiconductor device in order according to some example embodiments. FIGS. 8A to 8H may describe an example embodiment of a manufacturing method for manufacturing the semiconductor device in FIGS. 2A to 4B. FIGS. 8A to 8H may also illustrate cross-sections corresponding to FIGS. 3A and 4A, respectively.

Referring to FIG. 8A, active structures may be formed by alternately stacking sacrificial layers 120 and first to fourth channel layers 141, 142, 143, and 144 on a substrate 101, and may form preliminary lower isolation layers 130Lp on the active structures.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The active structures may include sacrificial layers 120 and first to fourth channel layers 141, 142, 143, and 144 which may be alternately stacked, and may further include active regions 105 formed by removing a portion of the substrate 101 and protruding from the substrate 101. In the key region KR, the active structures may further include dummy active regions 105D instead of the active regions 105.

The active structures may be formed using the first mask layer ML1 as a hard mask layer. The active structures may be formed in a line shape extending in one direction, for example, the X-direction, and may be spaced apart from each other in the Y-direction. The active regions 105 may further include impurities. The impurities may be implanted in a subsequent process.

The sacrificial layers 120 may be replaced with gate dielectric layers 162 and gate electrodes 165 through a subsequent process as in FIG. 3A. The sacrificial layers 120 may be formed of a material having etch selectivity with respect to each of the first to fourth channel layers 141, 142, 143, and 144. The first to fourth channel layers 141, 142, 143, and 144 may include a material different from a material of the sacrificial layers 120. The sacrificial layers 120 and the first to fourth channel layers 141, 142, 143, and 144 may include a semiconductor material including at least one of, for example, silicon (Si), silicon germanium (SiGe), or germanium (Ge), may include different materials, and may or may not include impurities. For example, the sacrificial layers 120 may include silicon germanium (SiGe), and the first to fourth channel layers 141, 142, 143, and 144 may include silicon (Si). The sacrificial layers 120 and the first to fourth channel layers 141, 142, 143, and 144 may be formed by performing an epitaxial growth process from the substrate 101.

The preliminary lower isolation layer 130Lp may form the lower isolation structure 130L in FIG. 3A through a subsequent process. The preliminary lower isolation layer 130Lp may be conformally deposited to cover the active structures. In the circuit region CR, the preliminary lower isolation layer 130Lp may fill gaps between adjacent active structures. In the key region KR, a spacing between the active structures may be relatively large, such that the preliminary lower isolation layer 130Lp may not completely fill the gaps between the adjacent active structures.

Referring to FIG. 8B, a lower isolation structure 130L may be formed by removing a portion of the preliminary lower isolation layer 130Lp, and a device isolation layer 110 and a dummy device isolation layer 110D may be formed.

The preliminary lower isolation layer 130Lp may be partially removed, for example, by an etch-back process. In the circuit region CR, the lower isolation structure 130L may be formed by remaining between the adjacent active structures. In the key region KR, the preliminary lower isolation layer 130Lp may be partially or entirely removed. Thereafter, the exposed first mask layer ML1 may be removed.

The device isolation layer 110 and the dummy device isolation layer 110D may be formed by depositing an insulating material to fill a region between the active structures, and exposing at least a portion of the active regions 105 and the dummy active regions 105D by removing a portion of the deposited insulating material from an upper portion. In this process, the level of the upper surfaces of the device isolation layer 110 and the dummy device isolation layer 110D and the shapes of the upper surfaces may be varied.

Referring to FIG. 8C, a sacrificial gate structure 200 may be formed on the active structures.

The sacrificial gate structure 200 may be configured as a sacrificial structure formed in regions in which the gate dielectric layers 162, the gate electrode 165, and the gate capping layer 167 are disposed on the channel structures 140 through a subsequent process as illustrated in FIG. 3A. The sacrificial gate structure 200 may have a line shape extending in one direction intersecting the active structures. The sacrificial gate structure 200 may extend, for example, in the Y-direction.

The sacrificial gate structure 200 may include first and second sacrificial gate layers 202 and 205 and a mask pattern layer 206 which may be stacked in order. The first and second sacrificial gate layers 202 and 205 may be patterned using the mask pattern layer 206. The first and second sacrificial gate layers 202 and 205 may be an insulating layer and a conductive layer, respectively, but example embodiments are not limited thereto, and the first and second sacrificial gate layers 202 and 205 may be formed as an integrated layer. For example, the first sacrificial gate layer 202 may include silicon oxide, and the second sacrificial gate layer 205 may include polysilicon. The mask pattern layer 206 may include silicon oxide and/or silicon nitride.

Referring to FIG. 8D, sidewall spacer layers 125 and dummy sidewall spacer layers 125D may be formed, and a portion of the active structures may be removed.

First, preliminary spacer layers including an insulating material may be conformally formed to cover the active structures and the sacrificial gate structures 200. An etch-back process may be performed in the circuit region CR such that the preliminary spacer layers may remain on both sidewalls of the active structures and sidewalls of the sacrificial gate structures 200, thereby forming the sidewall spacer layers 125 and the gate spacer layers 164 in FIG. 3A. In the key region KR, for example, by forming a sacrificial mask layer and removing the layer only from the active structures, the preliminary spacer layers may remain on the dummy device isolation layer 110D and may form dummy sidewall spacer layers 125D.

Thereafter, the exposed sacrificial layers 120 and the first to fourth channel layers 141, 142, 143, and 144 may be partially removed, and the active regions 105 and dummy active regions 105D may be partially removed. Due to the difference in widths and pitches of the active structures in the circuit region CR and the key region KR, a level of the upper surfaces of the active regions 105 may be different from a level of the upper surfaces of the dummy active regions 105D, but example embodiments are not limited thereto.

During a process of removing a portion of the active structures, heights of the sidewall spacer layers 125, the gate spacer layers 164, and the dummy sidewall spacer layers 125D may be reduced. In this process, heights of the dummy sidewall spacer layers 125D may be the same as or greater than heights the sidewall spacer layers 125. By this process, the first to fourth channel layers 141, 142, 143, and 144 may form channel structures 140 having a limited length in the X-direction.

In some example embodiments in FIGS. 7A and 7B, in this process, the active regions 105 and the dummy active regions 105D may be further removed up to the region in which the epitaxial layer 107 and the dummy epitaxial layers 107D are disposed, and the epitaxial layer 107 and the dummy epitaxial layers 107D may be formed.

Referring to FIG. 8E, a patterned second mask layer ML2 may be formed.

The second mask layer ML2 may be formed on the entire structure which is in the process of being manufactured. The second mask layer ML2 may include at least one hard mask layer. For example, the hard mask layer may include at least one of tonen silazene (TOSZ), silicon oxide, silicon nitride, silicon oxynitride, or spin on hardmask (SOH).

The second mask layer ML2 may be patterned by a photolithography process and an etching process and may have first and second openings OP1 and OP2 in regions corresponding to the upper isolation structure 130U in FIG. 3A and the dummy upper isolation structure 130D in FIG. 4A, respectively. Depths of the first and second openings OP1 and OP2 may be substantially the same. A level of a lower end of the second openings OP2 may be the same as or lower than a level of an upper end of the dummy sidewall spacer layers 125D. When the level of the lower end of the second openings OP2 is lower than the level of the upper end of the dummy sidewall spacer layers 125D, the second openings OP2 may be formed by removing a portion of the dummy sidewall spacer layers 125D.

Referring to FIG. 8F, the preliminary upper isolation layer 130Up filling the first and second openings OP1, OP2 may be formed.

The preliminary upper isolation layer 130Up may form the upper isolation structure 130U in FIG. 3A and the dummy upper isolation structure 130D in FIG. 4A through a subsequent process. The preliminary upper isolation layer 130Up may fill the first opening OP1. The preliminary upper isolation layer 130Up may not fill the second openings OP2 in the second openings OP2 having a relatively great thickness and may be conformally deposited along a bottom surface and internal sidewalls of the second openings OP2.

Referring to FIG. 8G, by removing the second mask layer ML2, the upper isolation structure 130U and the dummy upper isolation structure 130D may be formed.

First, the preliminary upper isolation layer 130Up on the second mask layer ML2 may be removed, and the second mask layer ML2 may be removed. The second mask layer ML2 may be selectively removed with respect to the preliminary upper isolation layer 130Up, the sidewall spacer layers 125, and the dummy sidewall spacer layers 125D, for example, using a wet etching process.

In this process, a portion formed in the dummy sidewall spacer layers 125D of the second mask layer ML2 material may remain because the portion may not be exposed to an etchant due to the dummy sidewall spacer layers 125D and the dummy upper isolation structure 130D. The other portion of the remaining second mask layer ML2 may be referred to as the mask insulating layer 115. In this process, in the key region KR, the mask insulating layer 115 may remain between the dummy device isolation layer 110D and the dummy upper isolation structure 130D, such that the dummy upper isolation structure 130D may remain stably without collapsing.

Referring to FIG. 8H, source/drain regions 150 and gate structures 160 may be formed.

The source/drain regions 150 may be formed by growing from the active regions 105, for example, by a selective epitaxial process. The source/drain regions 150 may include impurities by in-situ doping and/or through an ion implantation process.

Thereafter, the insulating liner layers 155 and the first interlayer insulating layer 190 may be formed, and the sacrificial layers 120 and the sacrificial gate structure 200 may be removed. The sacrificial layers 120 and the sacrificial gate structure 200 may be selectively removed with respect to the gate spacer layers 164, the first interlayer insulating layer 190, the source/drain regions 150, and the channel structures 140. For example, when the sacrificial layers 120 include silicon germanium (SiGe) and the channel structures 140 include silicon (Si), the sacrificial layers 120 may be selectively removed by performing a wet etching process.

Gate dielectric layers 162 and gate electrodes 165 may be formed in the regions from which the sacrificial layers 120 and the sacrificial gate structures 200 are removed. The gate dielectric layers 162 may be formed to conformally cover internal surfaces of the regions. The gate electrodes 165 may be formed to completely fill the regions, and the gate electrodes 165 may be removed from an upper portion to a predetermined depth together with the gate dielectric layers 162 and the gate spacer layers 164, and the gate capping layers 167 may be formed in the removed regions.

During the processes, the upper isolation structure 130U and the dummy upper isolation structure 130D may be removed from an upper portion to a predetermined height, thereby lowering the height.

Thereafter, referring to FIGS. 3A and 4A, source contact plugs 170, gate contact plugs 180, upper contacts 185, and upper interconnection lines 188 may be formed.

First, the second interlayer insulating layer 192 may be formed, and source contact plugs 170 penetrating the second interlayer insulating layer 192 and the first interlayer insulating layer 190, and gate contact plugs 180 penetrating the second interlayer insulating layer 192 and the gate capping layers 167 may be formed. The upper contacts 185 and the upper interconnection lines 188 may be formed in order on the source contact plugs 170 and the gate contact plugs 180. When another interconnection structure is disposed on the upper interconnection lines 188, the interconnection structure may be further formed in this process. Accordingly, the semiconductor device 100 in FIGS. 2A to 4B may be manufactured.

In some example embodiments in FIGS. 7A and 7B, the processes as below may be further performed on a backside of the substrate 101 after the above-described process is performed.

First, the substrate 101, the active regions 105, and the dummy active regions 105D may be removed, and the substrate insulating layer 103 may be formed. Thereafter, a portion of the substrate insulating layer 103 and the epitaxial layer 107 may be removed, and a conductive material may be deposited, thereby forming the backside contact plug 175. Thereafter, the backside insulating layer 196 may be formed, and the backside interconnection line 189 connected to the backside contact plug 175 may be formed.

According to the aforementioned example embodiments, in a key structure including a dummy upper isolation structure formed simultaneously with an upper isolation structure isolating source/drain regions, by allowing the dummy upper isolation structure to overlap edge regions of the dummy active structure, a semiconductor device having improved reliability can be provided.

While the example embodiments have been illustrated and described above, it will be configured as apparent to those skilled in the art that modifications and variations could be made without departing from the scope as defined by the appended claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor device, comprising:
a substrate including first and second regions;
active regions on the first region and extending in a first direction;
a device isolation layer in the first region and defining the active regions;
gate structures on the first region, intersecting the active regions, and extending in a second direction;
a plurality of channel layers on the active regions, spaced apart from each other in a third direction perpendicular to an upper surface of the substrate, and surrounded by each of the gate structures;
source/drain regions in recess regions in which the active regions are recessed, the source/drain regions on first and second sides of the gate structures and connected to the plurality of channel layers; and
an isolation structure between the gate structures, between the plurality of channel layers, and between the source/drain regions adjacent to each other in the second direction, and the isolation structure including a lower isolation structure and an upper isolation structure on the lower isolation structure;
dummy active structures on the second region and including at least one dummy active region;
a dummy device isolation layer in the second region and defining the dummy active regions; and
a dummy upper isolation structure on the dummy device isolation layer and the dummy active structures and at least partly overlapping edge regions of the dummy active structures in the third direction, wherein
the dummy upper isolation structure includes first patterns extending in the first direction or the second direction, and second patterns connecting ends of the first patterns, and
at least a portion of the dummy upper isolation structure is at a same level as the upper isolation structure.

2. The semiconductor device of claim 1, wherein each of the first patterns includes two vertical portions spaced apart from each other in a direction perpendicular to an extension direction of each of the first patterns and a horizontal portion connecting the vertical portions to each other, the horizontal portion on a lower portion of the vertical portions.

3. The semiconductor device of claim 1, wherein each width of each of the first patterns is greater than a width of the upper isolation structure.

4. The semiconductor device of claim 1, wherein the upper isolation structure and the dummy upper isolation structure include a same insulating material.

5. The semiconductor device of claim 1, wherein the second region further includes a mask insulating layer between the dummy upper isolation structure and the dummy device isolation layer.

6. The semiconductor device of claim 5, wherein the dummy upper isolation structure covers an entire upper surface of the mask insulating layer.

7. The semiconductor device of claim 5, wherein the second region further includes a sidewall spacer layer covering a side surface of and a lower surface of each of the mask insulating layers.

8. The semiconductor device of claim 1, wherein the dummy active structures further include dummy epitaxial layers on the dummy active regions, respectively.

9. The semiconductor device of claim 1, wherein a spacing between the first patterns is smaller than each width of each of the first patterns.

10. The semiconductor device of claim 1, wherein the first region is configured as a circuit region in which transistors including the gate structures are disposed, and the second region is configured as a key region in which a key structure including the dummy upper isolation structure is disposed.

11. The semiconductor device of claim 1, wherein the at least one dummy active region extends in an extension direction of the first patterns.

12. The semiconductor device of claim 1, wherein
each of the dummy active structures includes a plurality of dummy active regions, and
the plurality of dummy active regions extend in a direction perpendicular to an extension direction of the first patterns and are spaced apart from each other in the extension direction.

13. A semiconductor device, comprising:
a substrate including a key region; and
first and second key structures on the key region,
wherein the first key structure includes,
first dummy active structures on the key region, extending in a first direction parallel to an upper surface of the substrate, and spaced apart from each other in a second direction perpendicular to the first direction, and
a first dummy upper isolation structure on the first dummy active structures and having first openings exposing a portion of each of the first dummy active structures in plan view,
wherein the second key structure includes,
second dummy active structures on the key region, extending in the second direction, and spaced apart from each other in the first direction, and
a second dummy upper isolation structure on the second dummy active structures and having second openings exposing a portion of each of the second dummy active structures in plan view.

14. The semiconductor device of claim 13, wherein another portion of each of the first dummy active structures, not exposed through the first openings, overlaps the first dummy upper isolation structure in plan view.

15. The semiconductor device of claim 13, wherein each of the first dummy active structures includes one dummy active region defined by a dummy device isolation layer in the substrate.

16. The semiconductor device of claim 13, wherein each of the second dummy active structures includes a plurality of dummy active regions defined by a dummy device isolation layer in the substrate.

17. The semiconductor device of claim 13, wherein lower surfaces of the first and second dummy upper isolation structures are vertically spaced apart from upper surfaces of the first and second dummy active structures, respectively.

18. The semiconductor device of claim 13, wherein the first and second dummy active structures include a semiconductor material, and the first and second dummy upper isolation structures include an insulating material.

19. A semiconductor device, comprising:
a substrate including a key region;
dummy active structures on the key region, extending in a first direction parallel to an upper surface of the substrate, spaced apart from each other in a second direction perpendicular to the first direction, and each including at least one dummy active region;
a dummy device isolation layer in the key region and defining the at least one dummy active region; and
a dummy upper isolation structure on the dummy device isolation layer and a portion of each of the dummy active structures, and the dummy upper isolation structure including first patterns extending in the first direction.

20. The semiconductor device of claim 19, wherein each of the first patterns has a U-shape.
